(19) United States
(12) Patent Application Publication
(10) Pub. No.: US 2009/0263751 A1
(43) Pub. Date: Oct. 22, 2009

(54) Methods for double patterning photoresist

(76) Inventors: Swaminathan Sivakumar, Beaverton, OR (US); Anna Lio, Portland, OR (US); Elliot Tan, Portland, OR (US); Charles Wallace, Portland, OR (US); Anant Jahagirdar, Hillsboro, OR (US)

Correspondence Address: INTEL CORPORATION;c/o CPA Global, P.O. BOX 52050, MINNEAPOLIS, MN, 55402, US

(21) Appl. No.: 12/148,826

(22) Filed: Apr. 22, 2008

(51) Int. Cl. G03F 7/38

(52) U.S. Cl. 430/323; 430/324

(57) ABSTRACT

Embodiments of methods for double patterning photoresist are generally described herein. Other embodiments may be described and claimed.

### FIELD OF THE INVENTION

The field of invention relates generally to the field of semiconductor integrated circuit manufacturing and, more specifically but not exclusively, relates to the formation of a composite mask pattern using double patterning methods.

### BACKGROUND INFORMATION

As semiconductor devices continue to be scaled to smaller sizes, lithography technology may not be able to pattern masking layers having a desired pitch. Accordingly, lithography may become a limiting factor in the scaling of semiconductor devices.

### BRIEF DESCRIPTION OF THE DRAWINGS

The present invention is illustrated by way of example and not as a limitation in the figures of the accompanying drawings, in which

FIG. 1 is a flowchart describing an embodiment of a fabrication process to form a composite mask using a double patterning technique.

FIG. 2 is a plan layout view of patterned photoresist on a target layer.

FIG. 3 is a cross-sectional view of FIG. 2 taken through section line A-A illustrating the device in FIG. 2.

FIG. 4 illustrates one embodiment of the device of FIG. 3 after doping the patterned photoresist.

FIG. 5 illustrates another embodiment of the device of FIG. 3 after doping the patterned photoresist.

FIG. 6 illustrates the device of FIG. 4 after coating the doped target layer with a second photoresist layer.

FIG. 7 is a plan layout view of the device of FIG. 6 after patterning the second photoresist layer to form a composite mask.

FIG. 8 is a cross-sectional view of FIG. 7 taken through section line B-B after etching a composite pattern in the doped target layer using the composite mask.

### DETAILED DESCRIPTION

An apparatus and methods for double patterning photoresist are described in various embodiments. In the following description, numerous specific details are set forth such as a description of a method to fabricate a composite mask that may be used to form features, such as a plurality of lines, trenches, bodies, or other definable structures in a layer or substrate that are too small or complicated to achieve in a single lithography step. One skilled in the relevant art will recognize that the invention can be practiced without one or more of the specific details, or with other methods, components, materials, etc. In other instances, well-known structures, materials, or operations are not shown or described in detail to avoid obscuring aspects of the invention.

It would be an advance in the art of semiconductor manufacturing to reduce the number of process steps required to form a composite mask pattern in a target layer or substrate using a double patterning or a multiple patterning process. Double patterning is used to pattern one or more layers on a substrate, or the substrate itself, to form devices (e.g., transistor fins, gate stacks, etc.) therein to enable scaling of semiconductor devices for a lithography ratio of imaged half-pitch to optical resolution limit (or exposure k1 factor) at approximately less than 0.30. Existing double patterning methods includes using multiple resist layers and a plurality of etch processes to pattern one or more underlying layers. It would be a further advance in the art to provide a method to prevent degradation of a resist pattern upon contact with solvents or aqueous solutions, even after the resist pattern is further exposed to electromagnetic energy, such as ultraviolet (UV) light at an appropriate wavelength.

These advances in the art would avoid issues that can otherwise arise using contemporary manufacturing methods such as thermal processing and/or a deep UV cure process. Resist patterns formed using lithography can degrade significantly upon treatment with solvents and aqueous solutions. For example, a resist pattern formed on a surface such as a substrate can be washed away by a miscible solvent and can be consumed to a significant degree by immiscible solvents. Contact between a resist pattern and an aqueous solution such as water can lead to swelling of the resist pattern, as would be expected when using a thermal process or a deep UV cure process to cross link and stabilize the resist. Additional barrier layers, such as a thin organic layer, may be applied to the resist pattern to avoid swelling of the resist pattern upon contact with aqueous solutions. However, the use of one or more barrier layers causes undesirable enlargement of patterned lateral dimensions. To achieve desired lateral dimensions, it is necessary to use smaller patterns to account for the expected enlargement of the pattern with the addition of one or more barrier layers. Application of the barrier layer thus increases the lithographic challenge.

Another issue that can arise using contemporary manufacturing methods is that a resist pattern, formed on a surface using a first exposure source, that is further exposed to a second electromagnetic source such as UV light and then developed through contact with a weak basic solution can lift from the surface. Unintended resist lifting is a source a defects in the manufacture of semiconductor devices and is avoided to prevent a decrease in manufacturing yield.

One such advance in the art may comprise providing a first patterned resist layer on a target layer and/or substrate. A dopant is incorporated in the first patterned resist layer. A second resist layer is coated on the target layer and/or substrate. The second resist layer is patterned to form a composite mask on the target layer and/or substrate. A composite pattern is etched in the target layer and/or substrate using the composite mask. This embodiment of a method for double patterning photoresist is very flexible as it may be applied to a variety of resist chemistries, the equipment necessary to perform the method is commercially available, the dopant may be incorporated in the resist at a controlled depth and energy to stabilize portions of the resist most sensitive to attacks by solvent and aqueous solutions thus preserving critical physical resist dimensions, dopant incorporated in the resist may be tuned independent of the resist thickness, and selection of fluorine as the incorporated dopant adds a hydrophobic characteristic to the resist pattern thereby resisting or substantially preventing swelling from water penetration and/or retention.

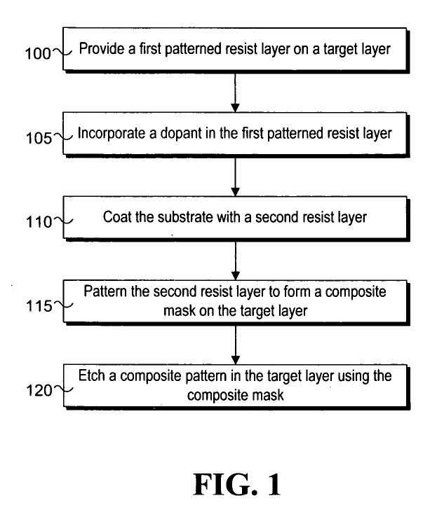

Turning now to the figures, the illustration in FIG. 1 is a flowchart describing an embodiment of a fabrication process to form a composite mask using a double patterning technique. The first patterned resist layer may be created through any number of known processes including known lithography processes. The first patterned resist layer (e.g., photo resist) is patterned as a plurality of features and/or lines where the lines are separated by a pitch (e.g., 160 nm). The pitch may be the minimum pitch attainable with lithography and/or may be twice a desired pitch if lithography can not obtain the desired pitch. The first patterned resist layer is formed on a target layer (element 100) wherein the target layer may be a dielectric layer, an active layer, or a substrate. A dopant is incorporated in the first patterned resist layer using an ion implantation process, an infusion process, or by plasma enhanced ion doping (element 105). The substrate is coated with a second resist layer in element 110 and the second resist layer is patterned to form a composite mask on the target layer in element 115. A composite pattern is etched in the target layer using a composite pattern in element 120. An advantage of the method described in FIG. 1 is that the double patterning process described is performed using two lithography processes and one etch process, as opposed to the two or more lithography processes and two etch processes used in contemporary double patterning processing.

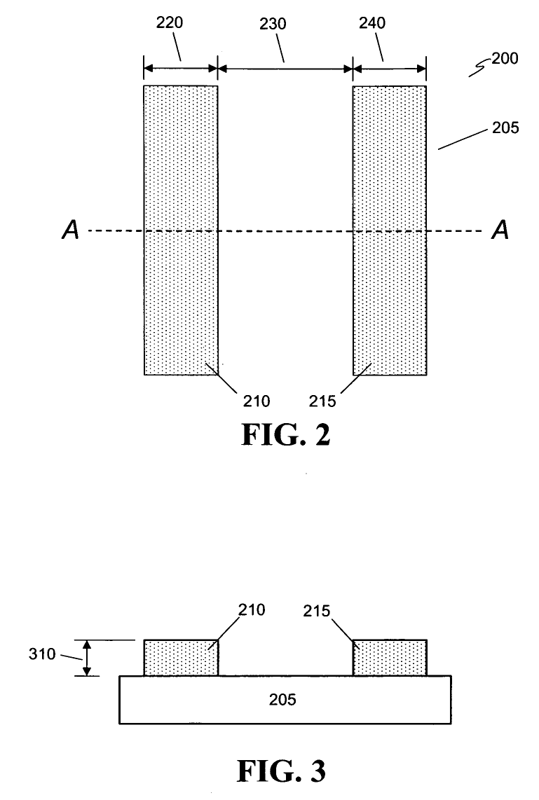

FIG. 2 is a plan layout view of patterned resist 200 on a target layer 205. A resist material used to form the patterned resist 200 is a light sensitive material used in industrial processes such as front end and/or back end semiconductor device processing. In one embodiment, the resist material is a positive photoresist where portions of the resist material exposed to light becomes soluble in a photoresist developer and portions not exposed to light remains relatively insoluble in a photoresist developer. In this embodiment, the resist material is formulated to react to light with a wavelength of approximately 193 nanometers (nm). In another embodiment, the resist material is formulated to react to light with a wavelength of approximately 248 nm. In a further embodiment, the patterned resist 200 is formed using negative tone imaging configurations comprising negative imaging in positive tone resists or use of negative tone resists.

The resist material may be a deep ultraviolet (DUV) resist and may further be chemically amplified to increase sensitivity to a desired exposure energy. The target layer 205 may be prepared prior to the application of the resist material using hexamethyldisilazane (HMDS) to prime the target layer 205 and promote adhesion of the resist material to the target layer 205. The words “photoresist” and “resist” are used interchangeably in the description and title.

The patterned resist 200 is comprised of a plurality of lines including a first line 210 with a first line width 220 and a second line 215 with a second line width 240 wherein the first line and the second line are separated by a gap 230. A pitch of the patterned resist is equal to the first line width 220 plus the gap 230. The target layer 205 may comprise one or more films typically used in contemporary device fabrication known to one skilled in the art, and/or alternatively the target layer 205 may be a substrate comprising silicon, gallium arsenide (GaAs), or indium antimonide (InSb) in monocrystalline form. The target layer 205 may further comprise buried layers such as a silicon on insulator layer.

The patterned resist 200 illustrated in FIG. 2 is a single layer of patterned resist, however the embodiment is not so limited. In another embodiment, the patterned resist 200 is a series of stacked organic and/or inorganic layers. For example, the stacked layers may comprise a plurality of organic films to provide desired optical masking characteristics. In one embodiment, the patterned resist 200 is formed using a series of processes known to one skilled in the art of lithography including resist coat, soft bake, exposure, post exposure bake, and develop.

FIG. 3 is a cross-sectional view of FIG. 2 taken through section line A-A illustrating the device in FIG. 2. The first line 210 is shown with a patterned resist thickness 310. The patterned resist thickness is dependent on a particular application. In one example, the patterned resist thickness 310 ranges between 800 and 2500 angstroms (Å) or preferably in a range between 1000 and 1500 Å, though the embodiment is not so limited.

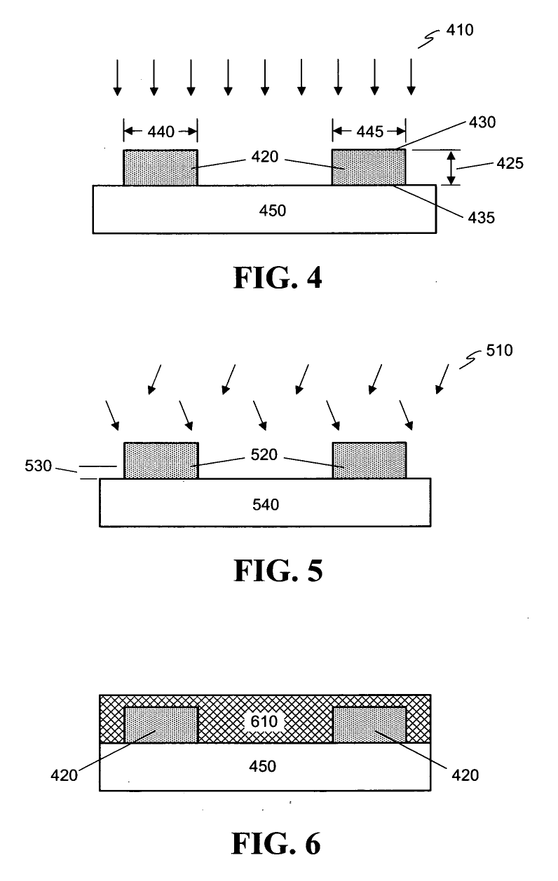

FIG. 4 illustrates one embodiment of the device of FIG. 3 after doping the patterned photoresist 200. In one embodiment, the patterned photoresist 200 and the target layer 205 is treated with a doping process 410 such as an ion implant process, an ion infusion process using a gas cluster ion beam (GCIB), or a plasma enhanced ion doping process to form a doped resist layer 420 and a doped target layer 450. The dopant may be delivered in the form of a single ion or a group of ions with one or more charges comprising one or more species of argon, nitrogen, fluorine, sulfur, tin, carbon, oxygen, silicon, germanium, boron, hydrogen, gallium, indium, nitrogen, aluminum, phosphorus, arsenic, and antimony.

In the embodiment illustrated in FIG. 4, a doped resist layer thickness 425 is doped from a doped resist layer top surface 430 to a doped resist layer bottom surface 435. In this embodiment, it has been found that to stabilize and render the doped resist layer substantially impervious to solvent and/or aqueous solutions attacks, it is necessary to incorporate dopant in the bottom third of the doped resist layer 420. The solvent is a liquid that would attack or dissolve a portion or all of the patterned resist 200 and may comprise a low boiling point organic material. In one example, to be substantially impervious means that a doped resist layer exposed to solvent and/or aqueous solutions would not measurably impact downstream device yields. In another example, to be substantially impervious means that feature sizes of a doped resist layer would be left undisturbed after exposure to a solvent and/or an aqueous solution.

Energy delivered by the ions breaks chemical bonds within the patterned resist 200 of FIG. 2 and favors formation of large polymer networks through crosslinking of resist molecules to form the doped resist layer 420. The application of fluorine as the dopant, as described earlier, provides an added characteristic to the doped resist layer 420 to render the doped resist layer 420 hydrophobic. Incorporation of fluorine in the doped resist layer 420 allows formation of thermodynamically favorable carbon-fluoride (C—F) bonds, thereby providing a dual mechanism for further stabilizing the doped resist layer 420. The formation of C—F bonds may further stabilize the photoresist against subsequent exposure to electromagnetic energy such as UV light, make it insoluble in developer solution and substantially impervious to water. The latter effect is important because, although cross-linked networks will inhibit molecular scale reactions that lead to dissolution of positive photoresist in developer, they cannot necessarily prevent water based solutions from penetrating and being retained inside photoresist.

The doped resist layer thickness 425 may be approximately the same thickness as the patterned resist thickness 310 of FIG. 3. Alternately, the doped resist layer thickness 425 may be smaller than the patterned resist thickness 310. Similarly, a first doped line width 440 may be equal to or smaller than the first line width 220 of FIG. 2 and a second doped line width 445 may be equal to or smaller than the second line width 240, thereby shrinking the patterned resist 200 and providing an additional benefit to an already unexpectantly useful method. An amount of shrinkage is dependent on resist chemistry type, patterned resist thickness 310, and dopant incorporation processing conditions such as dopant ion charge, energy, and dose. An amount of thickness shrinkage may be between 5 and 25 percent in one embodiment and between 10 and 20% in another embodiment. For example, a patterned resist thickness 310 of 1200 Å may result in a doped resist layer thickness 425 of 1000 Å after incorporating dopant in the resist according to the various methods described herein.

The embodiment illustrated in FIG. 4 indicates that ions from the doping process 410 are perpendicularly incident to the doped resist layer top surface 430. In another embodiment (illustrated in FIG. 5), ions from the doping process 410 arrive incident to the doped resist layer top surface 430 at an angle 0 to 60 degrees (incident angle) in a negative and/or positive direction from perpendicular. In a further embodiment, ions may arrive at the doped resist layer top surface 430 at a plurality of various angles.

In one embodiment, the incident angle is at least partly established using an ion implant or GCIB tool tilt angle. Further, the incident angle may be constrained as a function of the pitch of the patterned resist, for example due to shadowing effects. The doping process 410 may be characterized, at least in part, by the dopant species, energy, dose, and incident angle.

The energy range used in the dopant process 410 is related, at least in part, to the dopant species used in the dopant process 410. In one embodiment, an energy range used for the doping process 410 is between 5 and 25 thousand electron volts (KeV). The energy selected for the doping process 410 is designed to reduce or minimize damage to an underlying layer, such as the doped target layer 450 shown in FIG. 4 while forming the desired doped resist layer 420 without substantial decomposition or damage. The dose range in one embodiment ranges from 2.0 E14 to 2.0 E15 ions/cm². Dose used in the dopant process 410 is consistently established to provide a uniform dose across an entire surface of the doped target layer 450 or an even larger surface, such as a surface on a workpiece or substrate used in semiconductor manufacturing.

FIG. 5 illustrates another embodiment of the device of FIG. 3 after doping the patterned resist 200 to form a multipass doped resist layer 520 with a lower doped resist portion 530. In this embodiment, a multipass doping process 510, comprising two separate doping processes is used to distribute the dopant in the patterned resist 200 of FIG. 2. In one embodiment, a distribution profile for dopant in the multipass doped resist layer 520 as a function of resist thickness is a normal distribution profile or Gaussian profile.

In another embodiment, the distribution profile of dopant in the multipass doped resist layer 520 is established with the highest concentration of dopant in the lower doped resist portion 530. The multipass doping process 510 of FIG. 5 also forms the multipass doped target layer 540. A depth distribution profile of dopant in the multipass doped resist layer 520 is established as a function of energy of incident ions from an ion implant process, an ion infusion process, or a plasma enhanced ion doping process. Other process parameters such as tilt angle, resist material type, number of doping passes, and ion species may also be used to establish the distribution of dopant in the multipass doped resist layer 520.

In FIG. 5, the dopant in the multipass doped resist layer 520 is distributed throughout the entire multipass doped resist layer 520 including a lower doped resist portion 530, which may be one-third of the thickness of the multipass doped resist layer 520. In some embodiments, the multipass doped resist layer is soluble in a solvent or a subsequent deposition of resist material if the dopant is not distributed in the lower doped resist portion in a dose range between 2.0 E14 to 2.0 E15 ions/cm² using a doping process between 5 and 25 KeV.

FIG. 6 illustrates the device of FIG. 4 after coating the substrate with a second resist layer 610 to form two complementary patterns of resist without intermediate pattern transfer steps. The doped resist layer 420 is resistant to degradation or solubility in the second photoresist layer 610 as a result of the doping process 410 that crosslinks or stabilizes the patterned resist 200 of FIG. 2. The doped resist layer 420 is resistant to solvent attacks that would otherwise be damaging to photoresist. In some cases, the patterned resist 200 could be completely consumed when exposed to a miscible solvent, such as the solvent used to form the second photoresist layer 610.

In some embodiments, the doped resist layer 420 is resistant to immiscible solvents, such as water, that would otherwise deform or damage the patterned photoresist 200. For example, it has been demonstrated that a use of fluorine in the doping process 410 provides a doped resist layer 420 that is resistant to attacks by water. As an example, the patterned photoresist 200 when exposed to water may be susceptible to swelling, or an expansion of the patterned photoresist 200. Swelling of patterned photoresist 200 modifies a masked pattern so that placement and size of the masked pattern deviates from a desired pattern. Formation of the doped resist layer 420 provides a mechanism to preserve lateral dimensions and profiles of fine geometries, particularly those geometries with an exposure k1 factor of approximately equal to or less than 0.30. Further, formation of the doped resist layer 420 eliminates the need for an extra barrier layer that would otherwise be used to protect a masked pattern such as patterned resist 200. The extra barrier layer, while serving the purpose of shielding the masked pattern from miscible or immiscible solvents, also causes undesirable enlargement of patterned lateral dimensions. In addition, enlargement of patterned lateral dimensions due to application of the extra barrier layer can vary with feature geometry and size, leading to unexpected variation of patterned lateral dimensions.

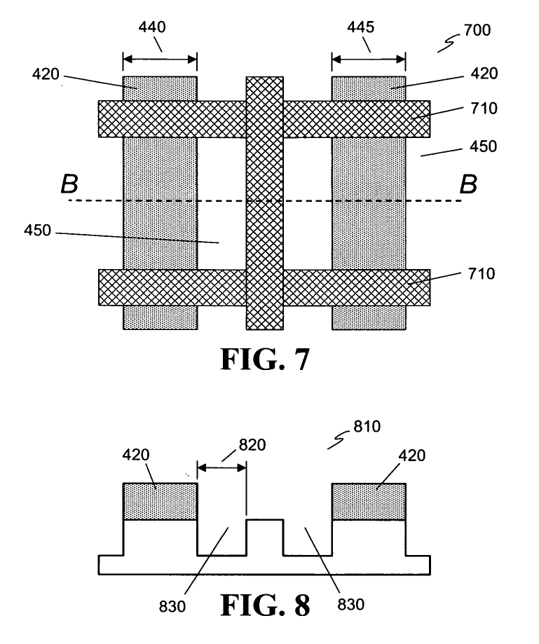

FIG. 7 is a plan layout view of the device of FIG. 6 after patterning the second photoresist layer to form a composite mask 700 using an embodiment of double patterning processing. In this embodiment, the composite mask 700 comprises the doped resist layer 420 with a first doped line width 440 and a second doped line width 445 and a second patterned resist layer 710 formed on the doped resist layer 420 and the doped target layer 450.

FIG. 8 illustrates the device of FIG. 7 after etching a composite pattern 810 with an etched feature size 820 in the doped target layer 450 using the composite mask 700 comprising doped resist layer 420. The embodiment shown in FIG. 8 illustrates a partially etched doped target layer 450 to form the composite pattern 810. In another embodiment (not shown), the doped target layer 450 is etched through the thickness of the doped target layer 450 to form a composite pattern 810 on an underlying layer or substrate. The composite pattern 810 may be formed using a dry etch process with sulfur hexafluoride (SF6), oxygen (O2), carbon monoxide (CO), and argon (Ar), or a fluorinated hydrocarbon (CHxFy) gas in a magnetically enhanced reactive ion etch (MERIE) or an electron cyclotron resonance (ECR) chamber or tool. The process chemistry employed is designed to selectively etch the doped target layer 450 to form the composite pattern 810 without substantially eroding or damaging the composite mask 700. The composite pattern is formed using double patterning to provide an etched feature size 820 of a trench 830 that would otherwise not be formed using an exposure k1 factor greater than 0.30.

A plurality of embodiments of methods for double patterning photoresist has been described. The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations.

However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method of forming a composite pattern in a doped target layer on a substrate, comprising:
providing a first patterned resist layer on a target layer;
incorporating a dopant in the first patterned resist layer and the target layer;
depositing a second resist layer on the doped resist layer and the doped target layer;
patterning the second resist layer to form a composite mask on the doped target layer;
etching the composite pattern in the doped target layer using the composite mask.

2. The method of claim 1, wherein the dopant is incorporated in the first patterned resist layer using a process selected from the group consisting of ion implantation, ion infusion, and plasma enhanced ion doping.

3. The method of claim 2, wherein the dopant is incorporated in a bottom third portion of the first patterned resist layer.

4. The method of claim 1, wherein the first patterned resist layer is substantially insoluble in the second resist layer.

5. The method of claim 1, wherein the dopant is selected from the group consisting of argon, nitrogen, fluorine, sulfur, tin, carbon, oxygen, silicon, germanium, boron, hydrogen, gallium, indium, nitrogen, aluminum, phosphorus, arsenic, and antimony.

6. The method of claim 5, wherein the first patterned resist layer doped with fluorine is substantially immiscible in a solvent or aqueous solution.

7. A method of crosslinking a resist pattern to form a composite mask on a substrate, comprising:
forming the resist pattern on a substrate;
incorporating a dopant in the resist pattern to crosslink the resist pattern and preserve features of the resist pattern;
depositing a second resist layer on the resist pattern and substrate;
patterning the second resist layer to form the composite mask on the substrate.

8. The method of claim 7, wherein the dopant is incorporated in the first patterned resist layer using a process selected from the group consisting of ion implantation, ion infusion, and plasma enhanced ion doping.

9. The method of claim 8, wherein the dopant is incorporated in a bottom third portion of the resist pattern.

10. The method of claim 7, wherein the resist pattern is substantially insoluble in the second resist layer.

11. The method of claim 7, wherein the dopant is selected from the group consisting of argon, nitrogen, fluorine, sulfur, tin, carbon, oxygen, silicon, germanium, boron, hydrogen, gallium, indium, nitrogen, aluminum, phosphorus, arsenic, and antimony.

12. The method of claim 11, wherein the resist layer doped with fluorine is substantially immiscible in water.

13. The method of claim 7, wherein the resist pattern and the second resist layer are formed from a common resist material.

14. A method for forming a composite mask on a target layer, comprising:
patterning a first resist layer on the target layer as a first plurality of lines separated by a first defined pitch;
incorporating a dopant in the first patterned resist layer to form a first doped patterned resist layer that is insoluble in a second resist layer;
depositing the second resist layer on the target layer and the first doped patterned resist layer;
patterning the second resist layer as a second plurality of lines separated by a second defined pitch, wherein a portion of the second plurality of lines is patterned between the first plurality of lines; and
etching the target layer to create a plurality of trenches in alignment with the first plurality of lines and the second plurality of lines.

15. The method of claim 14, wherein the dopant is incorporated in the first patterned resist layer using a process selected from the group consisting of ion implantation, ion infusion, and plasma enhanced ion doping.

16. The method of claim 14, wherein the dopant is incorporated in a bottom third portion of the first patterned resist layer.

17. The method of claim 14, wherein the dopant is selected from the group consisting of argon, nitrogen, fluorine, sulfur, tin, carbon, oxygen, silicon, germanium, boron, hydrogen, gallium, indium, nitrogen, aluminum, phosphorus, arsenic, and antimony.

18. The method of claim 17, wherein the resist layer doped with fluorine is substantially immiscible in water.

19. The method of claim 14, wherein the first resist layer and the second resist layer are formed from a common resist material.

20. The method of claim 19, wherein the first resist layer is substantially insoluble in the second resist layer.
